(19) United States
(12) Patent Application Publication
(10) Pub. No.: US 2017/0092848 A1
(43) Pub. Date: Mar. 30, 2017

(54) MAGNETIC MEMORY DEVICE AND METHOD FOR MANUFACTURING THE SAME

(71) Applicant: Samsung Electronics Co., Ltd., Suwon-si (KR)

(72) Inventors: Youngman Jang, Hwaseong-si (KR); Joonmyoung Lee, Anyang-si (KR); Keewon Kim, Suwon-si (KR); Yong Sung Park, Suwon-si (KR)

(21) Appl. No.: 15/210,627

(22) Filed: Jul. 14, 2016

(30) Foreign Application Priority Data
Sep. 25, 2015 (KR) 10-2015-0136183

(51) Int. Cl. H01L 43/08; H01L 43/10; H01L 43/02

(52) U.S. Cl. CPC H01L 43/08; H01L 43/02; H01L 43/10

(57) ABSTRACT

A magnetic memory device includes a magnetic tunnel junction pattern including a first free layer, a pinned layer, and a tunnel barrier layer between the first free layer and the pinned layer. The first free layer includes a first free magnetic pattern having a first surface in direct contact with the tunnel barrier layer and a second surface opposite to the first surface, and a second free magnetic pattern in contact with the second surface. The second free magnetic pattern includes iron-nickel (FeNi), and a nickel content of the second free magnetic pattern ranges from about 10 at % to about 30 at %.

### CROSS-REFERENCE TO RELATED APPLICATION

This U.S. non-provisional patent application claims priority under 35 U.S.C. §119 to Korean Patent Application No. 10-2015-0136183, filed on Sep. 25, 2015, in the Korean Intellectual Property Office, the disclosure of which is hereby incorporated by reference in its entirety.

### BACKGROUND

Embodiments of the inventive concepts relate to semiconductor devices and methods for manufacturing the same. More particularly, embodiments of the inventive concepts relate to magnetic memory devices and methods for manufacturing the same.

Semiconductor devices are widely used in an electronic industry because of their small sizes, multi-functional characteristics, and/or low manufacturing costs. Semiconductor memory devices among semiconductor devices may store logical data. Magnetic memory devices among semiconductor memory devices are spotlighted as the next-generation semiconductor memory device because of their high-speed and/or non-volatile characteristics.

Generally, a magnetic memory device may include a magnetic tunnel junction (MTJ) pattern. The MTJ pattern may include two magnetic layers and an insulating layer disposed between the two magnetic layers. A resistance value of the MTJ pattern may be changed depending on magnetization directions of the two magnetic layers. For example, if the magnetization directions of the two magnetic layers are anti-parallel to each other, the MTJ pattern may have a relatively high resistance value. When the magnetization directions of the two magnetic layers are parallel to each other, the MTJ pattern may have a relatively low resistance value. Logical data may be stored into and/or read out from the MTJ pattern by using a difference between these resistance values.

### SUMMARY

Embodiments of the inventive concepts may provide magnetic memory devices having improved reliability and a relatively low switching current.

Embodiments of the inventive concepts may provide methods for manufacturing a magnetic memory device having improved reliability and a relatively low switching current.

In an aspect, a magnetic memory device may include a magnetic tunnel junction pattern including a first free layer, a pinned layer, and a tunnel barrier layer disposed between the first free layer and the pinned layer. The first free layer may include a first free magnetic pattern having a first surface in direct contact with the tunnel barrier layer and a second surface opposite to the first surface, and a second free magnetic pattern in contact with the second surface of the first free magnetic pattern. The second free magnetic pattern may include iron-nickel (FeNi), and a nickel content of the second free magnetic pattern may range from about 10 at % to about 30 at %.

In some embodiments, the second free magnetic pattern may further include at least one of cobalt (Co) or boron (B).

In some embodiments, the nickel content of the second free magnetic pattern may be greater than that of the first free magnetic pattern.

In some embodiments, the first free magnetic pattern may include cobalt-iron-boron (CoFeB).

In some embodiments, a thickness of the second free magnetic pattern may be smaller than a thickness of the first free magnetic pattern.

In some embodiments, a thickness of the first free layer may range from about 10 Å to about 20 Å, and a thickness of the second free magnetic pattern may range from about 3 Å to about 10 Å.

In some embodiments, the magnetic memory device may further include a non-magnetic metal layer adjacent to the first free layer, and a second free layer spaced apart from the first free layer with the non-magnetic metal layer interposed therebetween. The nickel content of the second free magnetic pattern may be greater than that of the second free layer.

In some embodiments, the magnetic memory device may further include a capping layer spaced apart from the tunnel barrier layer with the first free layer interposed therebetween. The capping layer may include a metal oxide.

In some embodiments, the pinned layer may include a plurality of pinned layers. The plurality of pinned layers may include a first pinned layer adjacent to the tunnel barrier layer, and a second pinned layer spaced apart from the tunnel barrier layer with the first pinned layer interposed therebetween. In this case, the magnetic memory device may further include an exchange coupling layer between the first and second pinned layers.

In some embodiments, the first pinned layer may include a first magnetic layer adjacent to the tunnel barrier layer, and a second magnetic layer spaced apart from the tunnel barrier layer with the first magnetic layer interposed therebetween. The second magnetic layer may be in contact with the first magnetic layer.

In some embodiments, the magnetic tunnel junction pattern may be on a substrate, and the pinned layer may be between the substrate and the tunnel barrier layer.

In some embodiments, the magnetic tunnel junction pattern may be on a substrate, and the first free layer may be between the substrate and the tunnel barrier layer.

In some embodiments, the magnetic tunnel junction pattern may be on a substrate, and a magnetization direction of the first free layer and a magnetization direction of the pinned layer may be substantially perpendicular to a top surface of the substrate.

In some embodiments, the magnetic tunnel junction pattern may be on a substrate, and a magnetization direction of the first free layer and a magnetization direction of the pinned layer may be substantially parallel to a top surface of the substrate.

In some embodiments, the magnetic memory device may further include a pinning layer spaced apart from the tunnel barrier layer with the pinned layer interposed therebetween. The pinning layer may include an anti-ferromagnetic material, and the magnetization direction of the pinned layer may be fixed by the pinning layer in one direction substantially parallel to the top surface of the substrate.

In an aspect, a magnetic memory device may include a magnetic tunnel junction pattern including a free layer, a pinned layer, and a tunnel barrier layer between the free layer and the pinned layer. The free layer may include a first free magnetic pattern adjacent to the tunnel barrier layer, and a second free magnetic pattern spaced apart from the tunnel barrier layer with the first free magnetic pattern interposed therebetween. The second free magnetic pattern may be adjacent to the first free magnetic pattern. The first free magnetic pattern may include cobalt-iron-boron (CoFeB), and the second free magnetic pattern may include iron-nickel (FeNi). A nickel content of the second free magnetic pattern may range from about 10 at % to about 30 at %.

In some embodiments, the second free magnetic pattern may further include boron (B), and a boron content of the second free magnetic pattern may range from about 1 at % to about 25 at %.

In some embodiments, the first and second free magnetic patterns may be magnetically connected to each other.

In an aspect, a magnetic memory device may include a magnetic tunnel junction pattern including a free layer, a pinned layer, and a tunnel barrier layer between the free layer and the pinned layer. The free layer may include a first free magnetic pattern and a second free magnetic pattern. The second free magnetic pattern may be magnetically connected to the first free magnetic pattern. The second free magnetic pattern may include iron-nickel (FeNi), and a nickel content of the second free magnetic pattern may range from about 10 at % to about 30 at %. The nickel content of the second free magnetic pattern may be greater than that of the first free magnetic pattern.

In an aspect, a method for manufacturing a magnetic memory device may include forming a preliminary free layer, a preliminary pinned layer, and a preliminary tunnel barrier layer being formed between the preliminary free layer and the preliminary pinned layer on a substrate, and performing a thermal treatment process after the forming of the preliminary free layer, the preliminary pinned layer, and the preliminary tunnel barrier layer. The preliminary free layer may include a first free magnetic layer adjacent to the preliminary tunnel barrier layer, and a second free magnetic layer spaced apart from the preliminary tunnel barrier layer with the first free magnetic layer interposed therebetween. The second free magnetic layer may be adjacent to the first free magnetic layer. The second free magnetic layer may include iron-nickel (FeNi), and a nickel content of the second free magnetic layer may range from about 10 at % to about 30 at %.

In some embodiments, the method may further include patterning the preliminary free layer, the preliminary pinned layer, and the preliminary tunnel barrier layer to form a magnetic tunnel junction pattern including a free layer, a pinned layer, and a tunnel barrier layer between the free layer and the pinned layer.

In some embodiments, a process temperature of the thermal treatment process may range from 350° C. to 450° C.

In some embodiments, the nickel content of the second free magnetic layer may be greater than that of the first free magnetic layer.

In a further aspect, a magnetic memory device includes a magnetic tunnel junction pattern comprising a free layer, a pinned layer, and a tunnel barrier layer between the free layer and the pinned layer. The free layer comprises a first free magnetic pattern and a second free magnetic pattern on the first free magnetic pattern such that the first free magnetic pattern is between the second free magnetic pattern and the tunnel barrier layer, the second free magnetic pattern having a nickel content that is greater than a nickel content of the first free magnetic pattern.

In some embodiments, the nickel content of the second free magnetic pattern has an atomic percent between about 10 at % and about 30 at % and the first free magnetic pattern does not contain nickel.

In some embodiments, a boron content of the first free magnetic pattern has an atomic percent about 20 at % and a boron content of the second free magnetic pattern has an atomic percent between about 1 at % and about 25 at %.

In some embodiments, the pinned layer comprises a first pinned layer, a second pinned layer, and an exchange coupling layer between the first pinned layer and the second pinned layer. The exchange coupling layer may comprise one of ruthenium, iridium, and rhodium.

In some embodiments, a thickness of the first free magnetic pattern is greater than a thickness of the second free magnetic pattern. A thickness of the first free layer is between about 10 Å and about 20 Å and a thickness of the second free magnetic pattern is between about 3 Å and about 10 Å.

In some embodiments, the tunnel barrier layer has first and second surfaces that form interfaces with the free layer and the pinned layer, respectively and a magnetization direction of the free layer and a magnetization direction of the pinned layer are substantially perpendicular to the first and second surfaces of the tunnel barrier layer.

In some embodiments, the tunnel barrier layer has first and second surfaces that form interfaces with the free layer and the pinned layer, respectively and a magnetization direction of the free layer and a magnetization direction of the pinned layer are substantially parallel to the first and second surfaces of the tunnel barrier layer.

It is noted that aspects of the inventive concepts described with respect to one embodiment, may be incorporated in a different embodiment although not specifically described relative thereto. That is, all embodiments and/or features of any embodiment can be combined in any way and/or combination. These and other aspects of the inventive concepts are explained in detail in the specification set forth below.

### BRIEF DESCRIPTION OF THE DRAWINGS

The inventive concepts will become more apparent in view of the attached drawings and accompanying detailed description.

FIG. 1 is a circuit diagram illustrating a unit memory cell of a magnetic memory device according to some embodiments of the inventive concepts.

FIGS. 2A, 2B, 3A, and 3B are schematic views illustrating magnetic tunnel junction patterns according to some embodiments of the inventive concepts.

FIG. 4 is a cross-sectional view illustrating a magnetic memory device according to some embodiments of the inventive concepts.

FIGS. 5A and 5B are cross-sectional views illustrating a method for manufacturing a magnetic memory device, according to some embodiments of the inventive concepts.

FIGS. 6-9 are cross-sectional views illustrating magnetic memory devices according to some embodiments of the inventive concepts.

FIG. 10 is a graph illustrating saturation magnetizations of free layers according to comparative examples and an experimental example of some embodiments of the inventive concepts.

FIG. 11 is a graph illustrating Gilbert damping parameters of free layers according to comparative examples and an experimental example of some embodiments of the inventive concepts.

FIG. 12 is a graph illustrating switching efficiencies of free layers according to comparative examples and an experimental example of some embodiments of the inventive concepts.

FIG. 13 is a graph illustrating a tunneling magnetic resistance (TMR) characteristic according to the nickel content in a free layer of some embodiments of the inventive concepts.

FIG. 14 is a graph illustrating a phase diagram of a FeNi alloy.

### DETAILED DESCRIPTION OF THE EMBODIMENTS

The inventive concepts will now be described more fully hereinafter with reference to the accompanying drawings, in which exemplary embodiments of the inventive concepts are shown. The inventive concepts and methods of achieving them will be apparent from the following exemplary embodiments that will be described in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art.

As used herein, the singular terms “a,” “an” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. Additionally, the embodiments in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes.

Furthermore, throughout this disclosure, directional terms such as “upper,” “intermediate,” “lower,” and the like may be used herein to describe the relationship of one element or feature with another, and the inventive concept should not be limited by these terms. Accordingly, these terms such as “upper,” “intermediate,” “lower,” and the like may be replaced by other terms such as “first,” “second,” “third,” and the like to describe the elements and features.

It will be understood that, although the terms “first,” “second,” etc. may be used herein to describe various elements, these elements should not be limited by these terms. These terms are only used to distinguish one element from another. Thus, a first element could be termed a second element without departing from the teachings of the present inventive concept.

Exemplary embodiments of aspects of the present inventive concepts explained and illustrated herein include their complementary counterparts. The same reference numerals or the same reference designators denote the same elements throughout the specification. Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.
The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits. Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

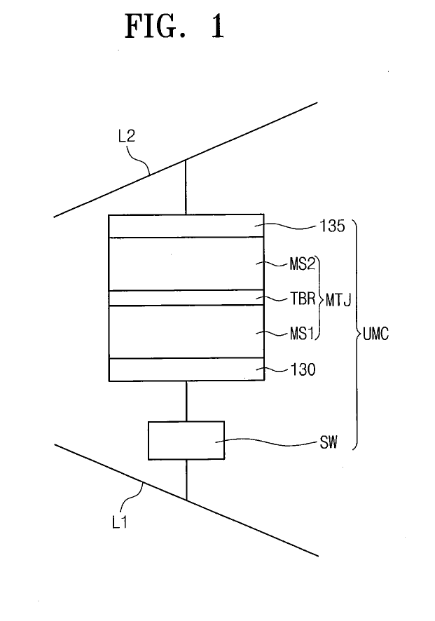

FIG. 1 is a circuit diagram illustrating a unit memory cell of a magnetic memory device according to some embodiments of the inventive concepts.

Referring to FIG. 1, a unit memory cell UMC may be connected between a first interconnection L1 and a second interconnection L2 that intersect each other. The unit memory cell UMC may include a selection element SW and a magnetic tunnel junction pattern MTJ. The selection element SW and the magnetic tunnel junction pattern MTJ may be electrically connected in series to each other. One of the first and second interconnections L1 and L2 may be used as a word line, and the other of the first and second interconnections L1 and L2 may be used as a bit line.

The selection element SW may selectively control a flow of charges passing through the magnetic tunnel junction pattern MTJ. For example, the selection element SW may be a diode, a PNP bipolar transistor, an NPN bipolar transistor, an NMOS field effect transistor, or a PMOS field effect transistor. When the selection element SW is a bipolar transistor or MOS field effect transistor having three terminals, an additional interconnection (not shown) may be connected to the selection element SW.

The magnetic tunnel junction pattern MTJ may include a first magnetic structure MS1, a second magnetic structure MS2, and a tunnel barrier layer TBR disposed between the first and second magnetic structures MS1 and MS2. Each of the first and second magnetic structures MS1 and MS2 may include at least one magnetic layer that is formed of a magnetic material. In some embodiments, the unit memory cell UMC may further include a first conductive structure 130 disposed between the first magnetic structure MS1 and the selection element SW, and a second conductive structure 135 disposed between the second magnetic structure MS2 and the second interconnection L2, as illustrated in FIG. 1.

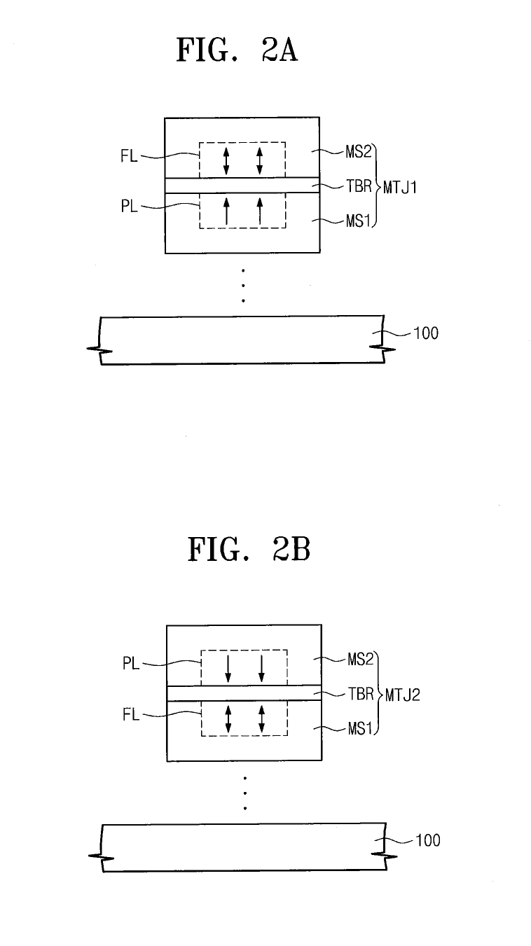

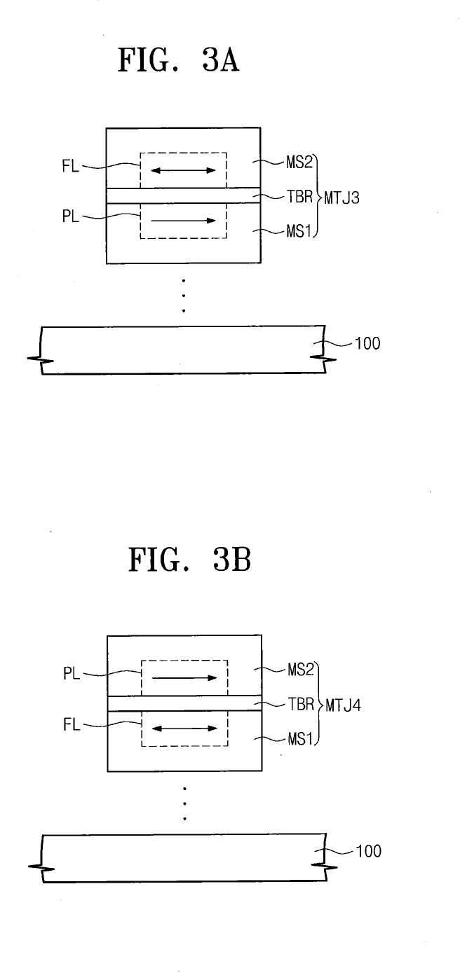

FIGS. 2A, 2B, 3A, and 3B are schematic views illustrating magnetic tunnel junction patterns according to some embodiments of the inventive concepts.

Referring to FIGS. 2A, 2B, 3A, and 3B, a magnetization direction of one of the magnetic layers of the first and second magnetic structures MS1 and MS2 may be fixed in a normal use environment regardless of an external magnetic field. Hereinafter, the magnetic layer having a fixed magnetization direction may be defined as a pinned magnetic pattern PL. A magnetization direction of the other of the magnetic layers of the first and second magnetic structures MS1 and MS2 may be switchable by a program magnetic field or program current applied thereto. Hereinafter, the magnetic layer having a switchable magnetization direction may be defined as a free magnetic pattern FL. The magnetic tunnel junction pattern MTJ may include at least one free magnetic pattern FL and at least one pinned magnetic pattern PL that are separated from each other by the tunnel barrier layer TBR.

An electrical resistance value of the magnetic tunnel junction pattern MTJ may be dependent on the magnetization directions of the free magnetic pattern FL and the pinned magnetic pattern PL. For example, the magnetic tunnel junction pattern MTJ may have a first electrical resistance value when the magnetization directions of the free and pinned magnetic patterns FL and PL are parallel to each other. The magnetic tunnel junction pattern MTJ may have a second electrical resistance value much greater than the first electrical resistance value when the magnetization directions of the free and pinned magnetic patterns FL and PL are anti-parallel to each other. As a result, the electrical resistance value of the magnetic tunnel junction pattern MTJ may be adjusted by changing the magnetization direction of the free magnetic pattern FL. This may be used as a data storing principle in a magnetic memory device according to some embodiments of the inventive concepts.

The first and second magnetic structures MS1 and MS2 of the magnetic tunnel junction pattern MTJ may be sequentially stacked on a substrate 100 as illustrated in FIGS. 2A, 2B, 3A, and 3B. In this case, the magnetic tunnel junction pattern MTJ may be one of various types according to a relative position of the free magnetic pattern FL on the basis of the substrate 100, a formation order of the free and pinned magnetic patterns FL and PL, and/or the magnetization directions of the free and pinned magnetic patterns FL and PL.

In some embodiments, the first and second magnetic structures MS1 and MS2 may respectively include magnetic layers having magnetization directions substantially perpendicular to a top surface of the substrate 100. In some embodiments, as illustrated in FIG. 2A, the magnetic tunnel junction pattern MTJ may be a first type magnetic tunnel junction pattern MTJ1 in which the first magnetic structure MS1 and the second magnetic structure MS2 include the pinned magnetic pattern PL and the free magnetic pattern FL, respectively. In certain embodiments, as illustrated in FIG. 2B, the magnetic tunnel junction pattern MTJ may be a second type magnetic tunnel junction pattern MTJ2 in which the first magnetic structure MS1 and the second magnetic structure MS2 include the free magnetic pattern FL and the pinned magnetic pattern PL, respectively.

In some embodiments, the first and second magnetic structures MS1 and MS2 may respectively include magnetic layers having magnetization directions substantially parallel to the top surface of the substrate 100. In some embodiments, as illustrated in FIG. 3A, the magnetic tunnel junction pattern MTJ may be a third type magnetic tunnel junction pattern MTJ3 in which the first magnetic structure MS1 and the second magnetic structure MS2 include the pinned magnetic pattern PL and the free magnetic pattern FL, respectively. In certain embodiments, as illustrated in FIG. 3B, the magnetic tunnel junction pattern MTJ may be a fourth type magnetic tunnel junction pattern MTJ4 in which the first magnetic structure MS1 and the second magnetic structure MS2 include the free magnetic pattern FL and the pinned magnetic pattern PL, respectively.

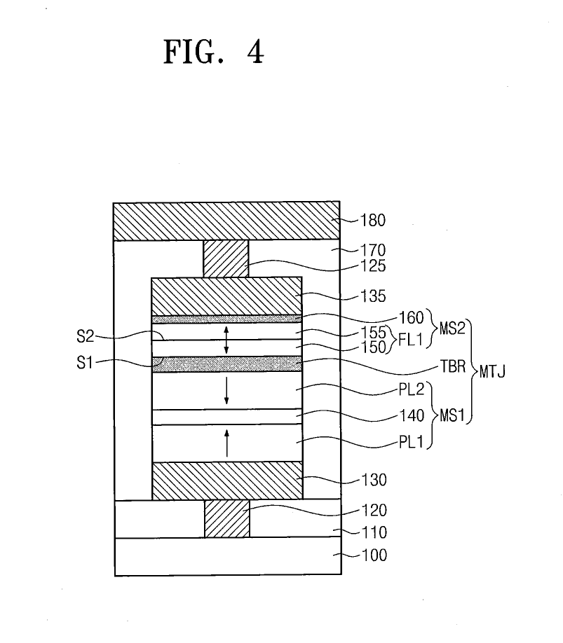

FIG. 4 is a cross-sectional view illustrating a magnetic memory device according to some embodiments of the inventive concepts.

Referring to FIG. 4, a first dielectric layer 110 may be disposed on a substrate 100, and a lower contact plug 120 may penetrate the first dielectric layer 110. A bottom surface of the lower contact plug 120 may be electrically connected to one terminal of a selection element.

The substrate 100 may include at least one of semiconductor materials, insulating materials, a semiconductor covered with an insulating material, or a conductor covered with an insulating material. In some embodiments, the substrate 100 may be a silicon wafer.

The first dielectric layer 110 may include at least one of an oxide (e.g., silicon oxide), a nitride (e.g., silicon nitride), or an oxynitride (e.g., silicon oxynitride). The lower contact plug 120 may include a conductive material. For example, the lower contact plug 120 may include at least one of a semiconductor material doped with dopants (e.g., doped silicon, doped germanium, or doped silicon-germanium), a metal (e.g., titanium, tantalum, or tungsten), or a conductive metal nitride (e.g., titanium nitride or tantalum nitride).

A first conductive structure 130, a first magnetic structure MS1, a tunnel barrier layer TBR, a second magnetic structure MS2, and a second conductive structure 135 may be sequentially stacked on the first dielectric layer 110. The first conductive structure 130 may be electrically connected to a top surface of the lower contact plug 120. The first magnetic structure MS1, the tunnel barrier layer TBR, and the second magnetic structure MS2 may constitute a magnetic tunnel junction pattern MTJ. The first conductive structure 130, the magnetic tunnel junction pattern MTJ, and the second conductive structure 135 may have sidewalls aligned with each other. Even though not shown in the drawings, the sidewalls of the first conductive structure 130, the magnetic tunnel junction pattern MTJ, and the second conductive structure 135 may have inclined profiles.

The first magnetic structure MS1 may include a first pinned layer PL1 on the first conductive structure 130, a second pinned layer PL2 on the first pinned layer PL1, and an exchange coupling layer 140 between the first pinned layer PL1 and the second pinned layer PL2. In other words, the first pinned layer PL1 may be disposed between the first conductive structure 130 and the exchange coupling layer 140, and the second pinned layer PL2 may be disposed between the exchange coupling layer 140 and the tunnel barrier layer TBR.

The second magnetic structure MS2 may include a first free layer FL1 on the tunnel barrier layer TBR, and a capping layer 160 on the first free layer FL1. In other words, the first free layer FL1 may be disposed between the tunnel barrier layer TBR and the capping layer 160.

The first and second pinned layers PL1 and PL2 may have magnetization directions substantially perpendicular to a top surface of the substrate 100. Likewise, a magnetization direction of the first free layer FL1 may also be substantially perpendicular to the top surface of the substrate 100.

In detail, the first pinned layer PL1 may have an easy axis substantially perpendicular to the top surface of the substrate 100. The magnetization direction of the first pinned layer PL1 may be fixed in one direction. Likewise, the second pinned layer PL2 may also have an easy axis substantially perpendicular to the top surface of the substrate 100. The magnetization direction of the second pinned layer PL2 may be fixed so as to be anti-parallel to the magnetization direction of the first pinned layer PL1 by the exchange coupling layer 140.

The magnetization direction of the first free layer FL1 may be changeable to be parallel or anti-parallel to the fixed magnetization direction of the second pinned layer PL2 by a program operation. In some embodiments, the magnetization direction of the first free layer FL1 may be changed by a spin torque transfer (STT) program operation. In other words, the magnetization direction of the first free layer FL1 may be changed using spin torque of electrons included in a program current.

The first conductive structure 130 may include a seed layer for forming the magnetic tunnel junction pattern MTJ and may function as an electrode electrically connecting the selection element to the magnetic tunnel junction pattern MTJ. In some embodiments, the first conductive structure 130 may include a first conductive layer and a second conductive layer that are sequentially stacked. In some embodiments, the first conductive layer may include tantalum (Ta) or cobalt-hafnium (Calf), and the second conductive layer may include ruthenium (Ru). The second conductive structure 135 may be in contact with the capping layer 160 and may function as an electrode electrically connecting the magnetic tunnel junction pattern MTJ to an interconnection 180. The second conductive structure 135 may have a single-layered or multi-layered structure including at least one of a precious metal layer, a magnetic alloy layer, or a metal layer. For example, the precious metal layer may include at least one of ruthenium (Ru), platinum (Pt), palladium (Pd), rhodium (Rh), or iridium (Ir). For example, the magnetic alloy layer may include at least one of cobalt (Co), iron (Fe), or nickel (Ni). For example, the metal layer may include at least one of tantalum (Ta) or titanium (Ti). However, embodiments of the inventive concepts are not limited thereto.

The first pinned layer PL1 may include a perpendicular magnetic material. In some embodiments, the first pinned layer PL1 may include cobalt-iron-terbium (CoFeTb) having a terbium content of 10% or more, cobalt-iron-gadolinium (CoFeGd) having a gadolinium content of 10% or more, cobalt-iron-dysprosium (CoFeDy), FePt having a L1₀ structure, FePd having the L1₀ structure, CoPd having the L1₀ structure, CoPt having the L1₀ structure, a CoPt alloy having a hexagonal close packed (HCP) crystal structure, or an alloy including at least one of the foregoing materials/compounds. In some embodiments, the first pinned layer PL1 may have a stack structure in which magnetic layers and non-magnetic layers are alternately and repeatedly stacked. For example, the stack structure may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where “n” denotes the number of bilayers.

The exchange coupling layer 140 may couple the magnetization direction of the first pinned layer PL1 to the magnetization direction of the second pinned layer PL2 in such a way that the magnetization direction of the first pinned layer PL1 is anti-parallel to the magnetization direction of the second pinned layer PL2. In some embodiments, the exchange coupling layer 140 may couple the first and second pinned layers PL1 and PL2 to each other by Ruderman-Klttel-Kasuya-Yosida (RKKY) interaction. Thus, magnetic fields generated by the magnetization directions of the first and second pinned layers PL1 and PL2 may offset each other to reduce or minimize a net magnetic field of the first magnetic structure MS1. As a result, it is possible to reduce or minimize the influence of the magnetic field of the first magnetic structure MS1 on the first free layer FL1. For example, the exchange coupling layer 140 may include at least one of ruthenium (Ru), iridium (Ir), or rhodium (Rh).

For example, the second pinned layer PL2 may have a single-layered or multi-layered structure including at least one of CoFeB, FeB, CoFeBTa, CoHf, Co, or CoZr. In some embodiments, the second pinned layer PL2 may have a single-layered structure having a CoFeB layer. In some embodiments, the second pinned layer PL2 may have a double-layered structure having a first magnetic layer and a second magnetic layer, which are stacked. For example, the second pinned layer PL2 may have a double-layered structure including a FeB layer and a CoFeB layer, a double-layered structure including a Co layer and a CoHf layer, or a double-layered structure including a CoFeBTa layer and a CoFeB layer.

In some embodiments, the first pinned layer PL1 and the exchange coupling layer 140 may be omitted. In this case, one surface of the second pinned layer PL2 may be in contact with the tunnel barrier layer TBR, and another surface of the second pinned layer PL2, opposite to the one surface, may be in contact with the first conductive structure 130.

The tunnel barrier layer TBR may be formed of a dielectric material. For example, the tunnel barrier layer TBR may include magnesium oxide (MgO), aluminum oxide (AlO), or a combination thereof.

The first free layer FL1 may include a first free magnetic pattern 150 on the tunnel barrier layer TBR, and a second free magnetic pattern 155 on the first free magnetic pattern 150. In detail, the first free magnetic pattern 150 may include a first surface S1 and a second surface S2 opposite to the first surface S1. The first surface S1 of the first free magnetic pattern 150 may be in contact with the tunnel barrier layer TBR. The second free magnetic pattern 155 may be spaced apart from the tunnel barrier layer TBR with the first free magnetic pattern 150 interposed therebetween. Here, the second surface S2 of the first free magnetic pattern 150 may be in contact with second free magnetic pattern 155.

The first free magnetic pattern 150 and the second free magnetic pattern 155 may be magnetically connected to each other. Thus, the first free layer FL1 may have one magnetization direction by the first and second free magnetic patterns 150 and 155 magnetically connected to each other. In other words, the first free layer FL1 may have a bi-layered structure in which two layers having different materials and/or different material contents are indivisibly connected to each other. Here, the first and second free magnetic patterns 150 and 155 may be in direct contact with each other as described above, or the first and second free magnetic patterns 150 and 155 may be magnetically connected to each other with a material layer (not shown) interposed therebetween.

Even though not shown in the drawings, the first and second free magnetic patterns 150 and 155 may be stacked in reverse order in some embodiments of the inventive concepts. In other words, the second free magnetic pattern 155 may be disposed between the tunnel barrier layer TBR and the first free magnetic pattern 150.

A thickness of the first free magnetic pattern 150 may be greater than that of the second free magnetic pattern 155. A sum of the thicknesses of the first and second free magnetic patterns 150 and 155 (e.g., a thickness of the first free layer FL1) may range from about 10 Å to about 20 Å. At this time, the thickness of the second free magnetic pattern 155 may range from about 3 Å to about 10 Å.

The first free magnetic pattern 150 may include boron (B). For example, the first free magnetic pattern 150 may include cobalt-iron-boron (CoFeB). The first free magnetic pattern 150 may be crystallized by a thermal treatment process to show a tunneling magnetic resistance (TMR) characteristic of the magnetic tunnel junction pattern MTJ. In some embodiments, the first free magnetic pattern 150 may be crystallized to have a body centered cubic (BCC) crystal structure. The atomic percent of boron in the first free magnetic pattern 150 may be about 20 at %.

The second free magnetic pattern 155 may include iron-nickel (FeNi). Optionally, the second free magnetic pattern 155 may further include at least one of cobalt (Co) or boron (B). For example, the second free magnetic pattern 155 may include at least one of iron-nickel (FeNi), iron-nickel-boron (FeNiB), cobalt-iron-nickel (CoFeNi), or cobalt-iron-nickel-boron (CoFeNiB). In addition, the second free magnetic pattern 155 may be additionally doped with a non-magnetic material, such as tungsten (W), molybdenum (Mo), tantalum (Ta), titanium (Ti), zirconium (Zr), or hafnium (Hf). In other words, the second free magnetic pattern 155 may include a magnetic alloy layer formed by doping at least one of the above listed alloys (i.e., FeNi, FeNiB, CoFeNi, and CoFeNiB) with the non-magnetic material (i.e., W, Mo, Ta, Ti, Zr, or Hf). The second free magnetic pattern 155 may be in a crystalline state, like the first free magnetic pattern 150. According to a composition ratio of iron-nickel (FeNi), the second free magnetic pattern 155 may have a BCC crystal structure, or a mixture crystal structure of the BCC crystal structure and a face centered cubic (FCC) crystal structure. In some embodiments, when a boron content of the second free magnetic pattern 155 is higher than about 15 at %, the second free magnetic pattern 155 may be in an amorphous state. However, embodiments of the inventive concepts are not limited thereto.

A nickel content of the second free magnetic pattern 155 may range from about 10 at % to about 30 at %. In other embodiments, the first free magnetic pattern 150 may not contain nickel (Ni). Thus, the nickel content of the second free magnetic pattern 155 may be greater than that of the first free magnetic pattern 150. When the second free magnetic pattern 155 includes boron (B), the boron content of the second free magnetic pattern 155 may range from about 1 at % to about 25 at %.

In the magnetic tunnel junction pattern MTJ, a switching current (Ic) may be theoretically proportional to each of a Gilbert damping parameter (α), a saturation magnetization (Ms) of a free layer, and a hard axis anisotropy field (Hk). Meanwhile, as an iron content in the iron-nickel (FeNi) alloy increases, the saturation magnetization (Ms) may decrease, but the Gilbert damping parameter (α) may increase. On the contrary, as a nickel content in the iron-nickel (FeNi) alloy increases, the saturation magnetization (Ms) may increase, but the Gilbert damping parameter (α) may decrease. Thus, the alloy may have a low saturation magnetization (Ms) and a low Gilbert damping parameter (α) in a suitable composition range of iron and nickel. In other words, as described above, the alloy may have a low saturation magnetization (Ms) and a low Gilbert damping parameter (α) when the nickel content in the alloy is in the range of about 10 at % to about 30 at %.

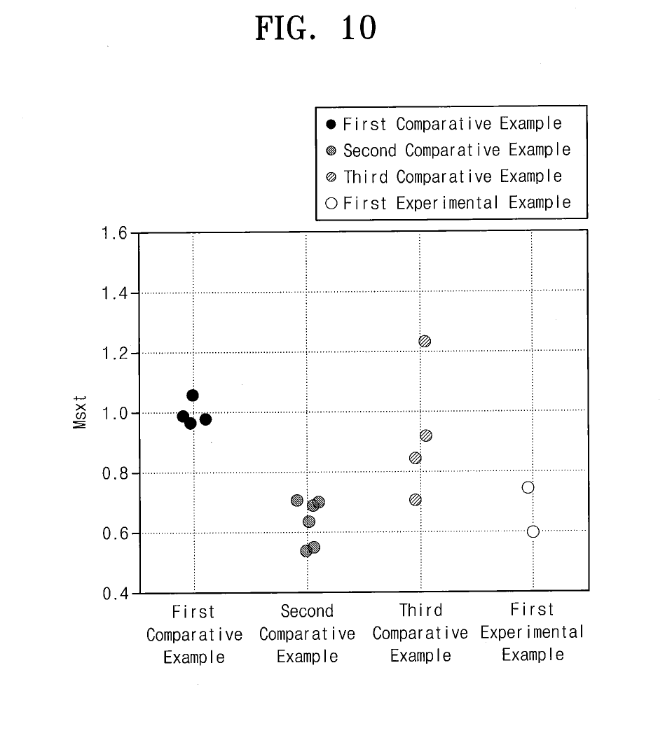

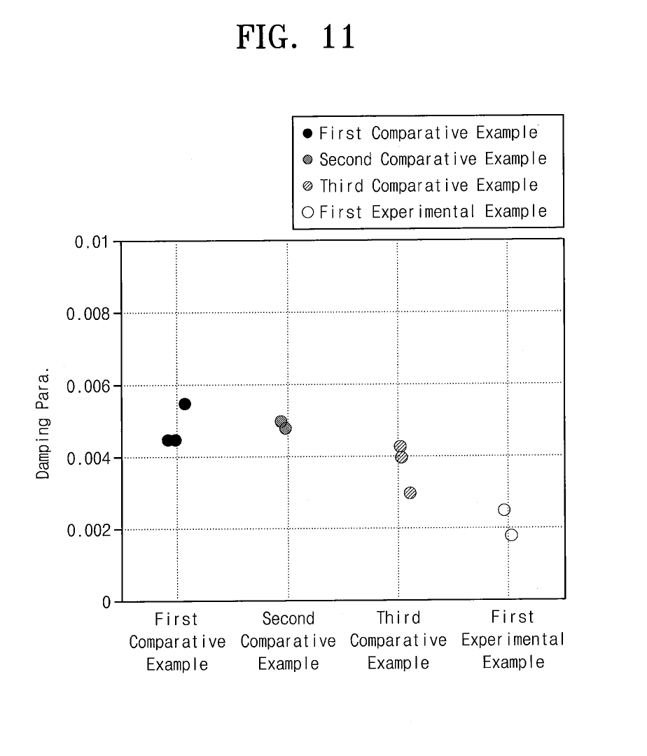

An experiment was performed to verify characteristics of the magnetic tunnel junction pattern according to some embodiments of the inventive concepts. In the experiment, first, second and third comparative examples and a first experimental example were prepared. The first comparative example was prepared to include a CoFeB layer, a non-magnetic metal layer (at least one of W, Mo, Cr, Ta, Hf, Zr, or Ti), and a CoFeB layer, which were sequentially stacked. The second comparative example was prepared to include a CoFeB layer and a CoFeBX layer (X=at least one of W, Mo, Cr, Ta, Hf, Zr, or Ti), which were sequentially stacked. The third comparative example was prepared to include a single CoFeB layer. The first experimental example was prepared to include a CoFeB layer and a FeNi layer (Ni content=15 at %), which were sequentially stacked. Saturation magnetizations (Ms) and thicknesses (t) of the first to third comparative examples and the first experimental example were measured. FIG. 10 shows a value of the saturation magnetization (Ms)×the thickness (t) of each of the first to third comparative examples and the first experimental example. In addition, the Gilbert damping parameters (α) of the first to third comparative examples and the first experimental example were measured, and the measured Gilbert damping parameters (α) are shown in FIG. 11.

Referring to FIGS. 10 and 11, it may be verified that the free layer additionally including the FeNi layer according to the first experimental example has a saturation magnetization (Ms) and a Gilbert damping parameter (α), which are lower than those of free layers of the first to third comparative examples. The first experimental example corresponds to the embodiments of the inventive concepts. In other words, the magnetic tunnel junction pattern MTJ according to some embodiments of the inventive concepts can have a low switching current (Ic).

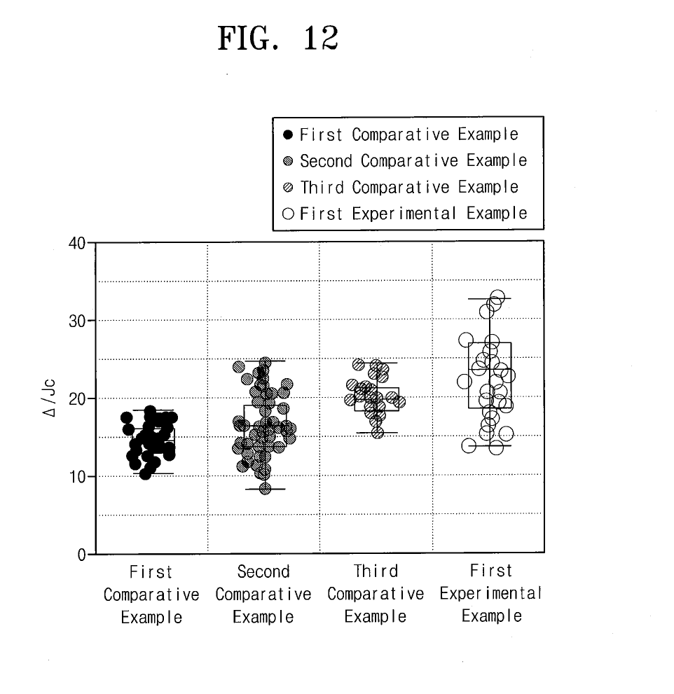

Δ/Jc values of the first to third comparative examples and the first experimental example were measured, the measured Δ/Jc values are shown in FIG. 12. “Δ” denotes thermal stability, and “Jc” denotes a critical current density. Thus, the Δ/Jc value denotes a switching efficiency of a magnetic memory device. Referring to FIG. 12, it may be verified that the Δ/Jc value of the free layer additionally including the FeNi layer of the first experimental example is higher than those of the free layers of the first to third comparative examples. In other words, it may be verified that the switching efficiency of the free layer according to some embodiments of the inventive concepts is improved.

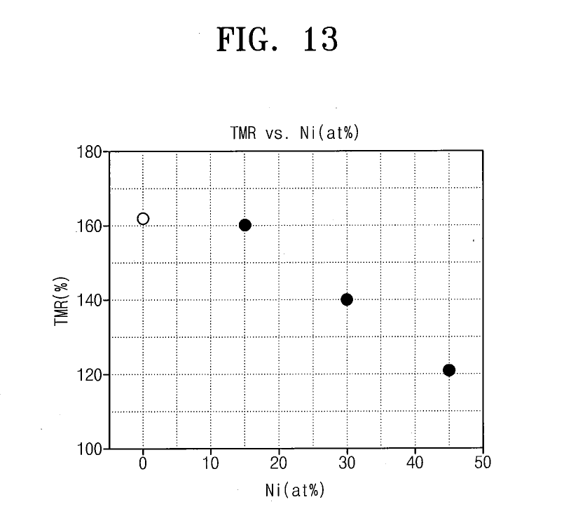

In another experiment, first to fourth samples were prepared. Each of the first to fourth samples was prepared to include a CoFeB layer and a FeNi layer sequentially stacked. Here, Ni contents in the FeNi layers of the first to fourth samples were 1 at %, 15 at %, 30 at %, and 45 at %, respectively. Tunneling magnetic resistance (TMR) values of the first to fourth samples were measured, and the measured TMR values are shown in FIG. 13.

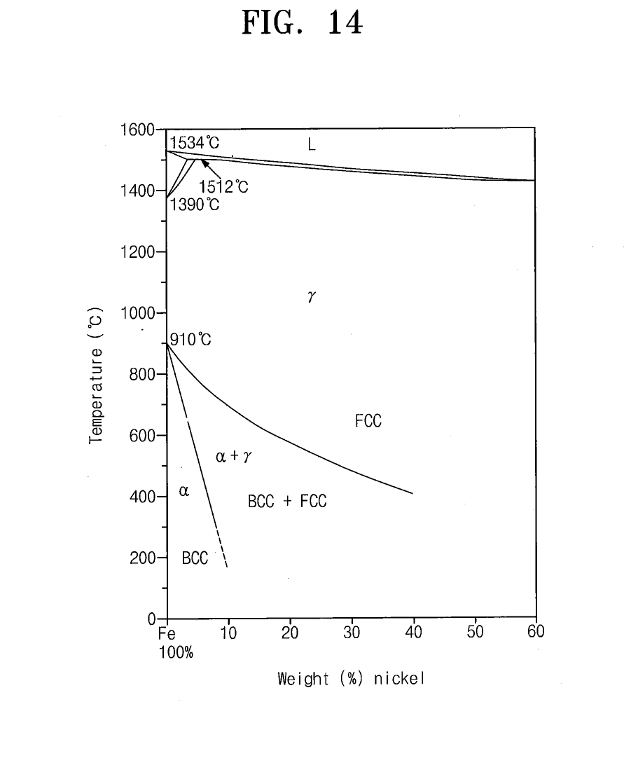

Referring to FIG. 13, it may be verified that the TMR value decreases as the Ni content increases. In particular, in a case in which the Ni content is higher than 30 at %, the TMR value may be small to be unsuitable for the magnetic tunnel junction pattern. FIG. 14 illustrates a phase diagram of a FeNi alloy. Referring to FIG. 14, in the case in which the Ni content is higher than 30 at %, the BCC crystal structure and the FCC crystal structure may exist together in the FeNi alloy to deteriorate the TMR characteristic. In addition, in a case in which the Ni content is very small (e.g., 1 at %), the Fe content may be too much to increase the saturation magnetization (Ms). Thus, a switching current (Ic) may be increased.

As a result, according to some embodiments of the inventive concepts, the Ni content in the second free magnetic pattern 155 magnetically connected to the second free magnetic pattern 150 may be adjusted in a suitable range in the first free layer FL1 having the bi-layered structure, and, thus, the switching current (Ic) may be reduced and the TMR characteristics may be improved.

Referring again to FIG. 4, the capping layer 160 may include a metal oxide. For example, the capping layer 160 may include at least one of tantalum oxide, magnesium oxide, titanium oxide, zirconium oxide, hafnium oxide, or zinc oxide. The capping layer 160 may assist the first free layer FL1 to have a magnetization direction substantially perpendicular to the top surface of the substrate 100. A resistance value of the capping layer 160 may be equal to or less than one third (⅓) of a resistance value of the tunnel barrier layer TBR.

A second dielectric layer 170 may be disposed on an entire top surface of the substrate 100 to cover the first conductive structure 130, the magnetic tunnel junction pattern MTJ, and the second conductive structure 135. An upper contact plug 125 may penetrate the second dielectric layer 170 so as to be connected to the second conductive structure 135. The second dielectric layer 170 may include at least one of an oxide (e.g., silicon oxide), a nitride (e.g., silicon nitride), or an oxynitride (e.g., silicon oxynitride). The upper contact plug 125 may include at least one of a metal (e.g., titanium, tantalum, copper, aluminum, or tungsten) or a conductive metal nitride (e.g., titanium nitride or tantalum nitride).

An interconnection 180 may be disposed on the second dielectric layer 170. The interconnection 180 may be connected to the upper contact plug 125. The interconnection 180 may include at least one of a metal (e.g., titanium, tantalum, copper, aluminum, or tungsten) or a conductive metal nitride (e.g., titanium nitride or tantalum nitride). In some embodiments, the interconnection 180 may be a bit line.

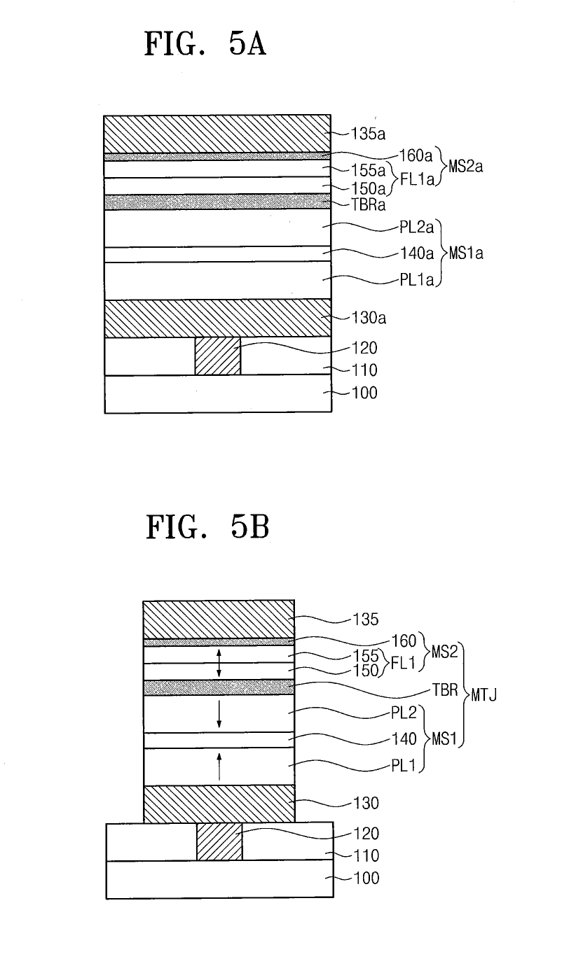

FIGS. 5A and 5B are cross-sectional views illustrating a method for manufacturing a magnetic memory device, according to some embodiments of the inventive concepts.

Referring to FIG. 5A, a first dielectric layer 110 may be formed on a substrate 100. A lower contact plug 120 may be formed to penetrate the first dielectric layer 110. A first preliminary conductive structure 130a may be formed on the first dielectric layer 110. The first preliminary conductive structure 130a may be electrically connected to a top surface of the lower contact plug 120.

Even though not shown in the drawings, a seed layer (not shown) may be formed on the first preliminary conductive structure 130a. The seed layer may be deposited using a physical vapor deposition (PVD) process, a chemical vapor deposition (CVD) process, or an atomic layer deposition (ALD) process. In some embodiments, the seed layer may be deposited by a sputtering process corresponding to a kind of the PVD process.

A first preliminary magnetic structure MS1a may be formed on the seed layer. The first preliminary magnetic structure MS1a may include a first preliminary pinned layer PL1a, a preliminary exchange coupling layer 140a, and a second preliminary pinned layer PL2a.

The first preliminary pinned layer PL1a may be deposited on the seed layer. The first preliminary pinned layer PL1a may be formed using the seed layer as a seed. In some embodiments, the first preliminary pinned layer PL1a may have the same crystal structure as the seed layer. The first preliminary pinned layer PL1a may include a perpendicular magnetic material. For example, the first preliminary pinned layer PL1a may include the same material as the first pinned layer PL1 described above with reference to FIG. 4.

The first preliminary pinned layer PL1a may be deposited by a PVD process, a CVD process, or an ALD process. In some embodiments, the first preliminary pinned layer PL1a may be deposited by a sputtering process. When the first preliminary pinned layer PL1a is formed of a CoPt alloy, the first preliminary pinned layer PL1a may be formed by the sputtering process using an argon (Ar) gas. In this case, to reduce a saturation magnetization of the first preliminary pinned layer PL1a, the first preliminary pinned layer PL1a may be formed of the CoPt alloy doped with boron (B).

The preliminary exchange coupling layer 140a may be deposited on the first preliminary pinned layer PL1a. In some embodiments, the preliminary exchange coupling layer 140a may be formed using the first preliminary pinned layer PL1a as a seed. For example, the preliminary exchange coupling layer 140a may be formed of ruthenium having a HCP crystal structure. The preliminary exchange coupling layer 140a may be deposited by a PVD process, a CVD process, or an ALD process. In some embodiments, the preliminary exchange coupling layer 140a may be deposited by a sputtering process.

The second preliminary pinned layer PL2a may be formed on the preliminary exchange coupling layer 140a. The second preliminary pinned layer PL2a may be formed using the preliminary exchange coupling layer 140a as a seed. In some embodiments, the second preliminary pinned layer PL2a may have the same crystal structure as the preliminary exchange coupling layer 140a. In some embodiments, the second preliminary pinned layer PL2a may include a perpendicular magnetic material. In some embodiments, the second preliminary pinned layer PL2a may include the same material as the second pinned layer PL2 described above with reference to FIG. 4. The second preliminary pinned layer PL2a may be deposited by a PVD process, a CVD process, or an ALD process. In some embodiments, the second preliminary pinned layer PL2a may be deposited by a sputtering process.

A preliminary tunnel barrier layer TBRa may be formed on the second preliminary pinned layer PL2a. In some embodiments, the preliminary tunnel barrier layer TBRa may be formed by a sputtering process using a tunnel barrier material as a target. The target may include the tunnel barrier material having accurately controlled stoichiometry. For example, the preliminary tunnel barrier layer TBRa may include at least one of magnesium oxide (MgO) or aluminum oxide (AlO). In some embodiments, the preliminary tunnel barrier layer TBRa may be formed of magnesium oxide (MgO) having a sodium chloride crystal structure.

A second preliminary magnetic structure MS2a may be formed on the preliminary tunnel barrier layer TBRa. The second preliminary magnetic structure MS2a may include a first preliminary free layer FL1a and a preliminary capping layer 160a. The first preliminary free layer FL1a may include a first free magnetic layer 150a and a second free magnetic layer 155a.

In some embodiments, the first free magnetic layer 150a and the second free magnetic layer 155a may be sequentially formed on the preliminary tunnel barrier layer TBRa. The first and second free magnetic layers 150a and 155a may be sequentially deposited by a PVD process, a CVD process, and/or an ALD process. In some embodiments, each of the first and second free magnetic layers 150a and 155a may be formed by a sputtering process. The deposited first and second free magnetic layers 150a and 155a may be in an amorphous state.

In some embodiments, the first free magnetic layer 150a may be formed of cobalt-iron-boron (CoFeB). In some embodiments, the second free magnetic layer 155a may be formed of at least one of iron-nickel (FeNi), iron-nickel-boron (FeNiB), cobalt-iron-nickel (CoFeNi), or cobalt-iron-nickel-boron (CoFeNiB). In addition, the second free magnetic layer 155a may be formed of a magnetic alloy layer realized by doping at least one of the above listed alloys (i.e., FeNi, FeNiB, CoFeNi, and CoFeNiB) with a non-magnetic material (i.e., W, Mo, Ta, Ti, Zr, or Hf). At this time, a nickel content in a target of the sputtering process for depositing the second free magnetic layer 155a may range from about 10 at % to about 30 at %.

A thermal treatment process may be performed after the formation of the first and second free magnetic layers 150a and 155a. The first free magnetic layer 150a and the second free magnetic layer 155a may be crystallized by the thermal treatment process. However, when the second free magnetic layer 155a contains boron (B) of about 15 at % or more, the second free magnetic layer 155a may remain in the amorphous state after the thermal treatment process. The first and second free magnetic layers 150a and 155a may show a tunneling magnetic resistance (TMR) characteristic by the thermal treatment process. In other words, the first and second free magnetic layers 150a and 155a may obtain a high magnetoresistance ratio. To obtain a sufficient magnetoresistance ratio, the thermal treatment process may be performed at a high temperature of 350° C. to 450° C. If the temperature of the thermal treatment process is lower than about 350° C., a sufficient magnetoresistance ratio may not be obtained. If the temperature of the thermal treatment process is higher than about 450° C., a switching error may occur by an increase in saturation magnetization (Ms) and an increase in resistance-area (RA) value. In some embodiments, the thermal treatment process may be performed at a high temperature of about 400° C.

The first free magnetic layer 150a may be crystallized using the preliminary tunnel barrier layer TBRa as a seed during the thermal treatment process. In some embodiments, the preliminary tunnel barrier layer TBRa may have a sodium chloride crystal structure, and, thus, the first free magnetic layer 150a may be crystallized to have a BCC crystal structure. The second free magnetic layer 155a may also be crystallized to have the BCC crystal structure.

In some embodiments, the second free magnetic layer 155a as well as the first free magnetic layer 150a may be crystallized by the thermal treatment process when the second free magnetic layer 155a contains boron (B) of about 15 at % or more.

The preliminary capping layer 160a and a second preliminary conductive structure 135a may be sequentially formed on the first preliminary free layer FL1a. In some embodiments, the thermal treatment process may be performed after the formation of the second preliminary conductive structure 135a. In some embodiments, the thermal treatment process may be performed after the formation of the first preliminary free layer FL1a and before the formation of the preliminary capping layer 160a. In some embodiments, the thermal treatment process may be performed after the formation of the preliminary capping layer 160a and before the formation of the second preliminary conductive structure 135a.

For example, the preliminary capping layer 160a may be formed of at least one of tantalum oxide, magnesium oxide, titanium oxide, zirconium oxide, hafnium oxide, or zinc oxide. The second preliminary conductive structure 135a may be formed to have a single-layered or multi-layered structure including at least one of a precious metal layer, a magnetic alloy layer, or a metal layer. For example, the second preliminary conductive structure 135a may be formed of the same material as the second conductive structure 135 described above with reference to FIG. 4.

Referring to FIG. 5B, the second preliminary conductive structure 135a, the preliminary capping layer 160a, the first preliminary free layer FL1a, the preliminary tunnel barrier layer TBRa, the second preliminary pinned layer PL2a, the preliminary exchange coupling layer 140a, the first preliminary pinned layer PL1a, and the first preliminary conductive structure 130a may be successively patterned to form a first conductive structure 130, a first pinned layer PL1, an exchange coupling layer 140, a second pinned layer PL2, a tunnel barrier layer TBR, a first free layer FL1, a capping layer 160, and a second conductive structure 135, which are sequentially stacked. The first free layer FL1 may include a first free magnetic pattern 150 on the tunnel barrier layer TBR, and a second free magnetic pattern 155 on the first free magnetic pattern 150.

Referring again to FIG. 4, a second dielectric layer 170 may be formed to cover the first conductive structure 130, the magnetic tunnel junction pattern MTJ, and the second conductive structure 135. An upper contact plug 125 may be formed to penetrate the second dielectric layer 170. The upper contact plug 125 may be connected to the second conductive structure 135. An interconnection 180 may be formed on the second dielectric layer 170. The interconnection 180 may be connected to the upper contact plug 125.

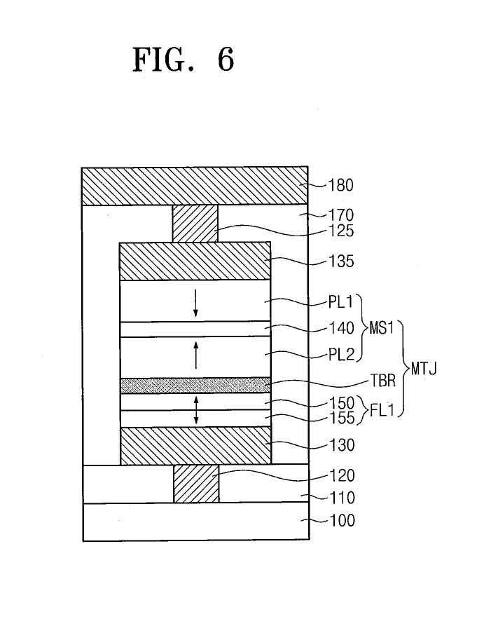

FIG. 6 is a cross-sectional view illustrating a magnetic memory device according to some embodiments of the inventive concepts. In the present embodiment, the same elements as described in the embodiment of FIG. 4 will be indicated by the same reference numerals or the same reference designators. For ease and convenience in explanation, the descriptions of the same elements as in the embodiment of FIG. 4 will be omitted or mentioned briefly. In other words, differences between the present embodiment and the embodiment of FIG. 4 will be mainly described hereinafter.

Referring to FIG. 6, the second type magnetic tunnel junction pattern MTJ2 of FIG. 2B may be provided on the substrate 100. In detail, a first magnetic structure MS1 may include a first free layer FL1, and a second magnetic structure MS2 may include first and second pinned layers PL1 and PL2. In other words, unlike the magnetic memory device according to the embodiment of FIG. 4, the first free layer FL1 may be disposed between the tunnel barrier layer TBR and the first conductive structure 130, and the first and second pinned layers PL1 and PL2 may be disposed between the tunnel barrier layer TBR and the second conductive structure 135.

The second magnetic structure MS2 may include the second pinned layer PL2 on the tunnel barrier layer TBR, the first pinned layer PL1 on the second pinned layer PL2, and the exchange coupling layer between the second pinned layer PL2 and the first pinned layer PL1. Unlike FIG. 4, the capping layer 160 under the second conductive structure may be omitted.

The first magnetic structure MS1 may include a first free magnetic pattern 150 under the tunnel barrier layer TBR, and a second free magnetic pattern 155 under the first free magnetic pattern 150. In some embodiments, the first free magnetic pattern 150 may include cobalt-iron-boron (CoFeB), and the second free magnetic pattern 155 may include at least one of iron-nickel (FeNi), iron-nickel-boron (FeNiB), cobalt-iron-nickel (CoFeNi), or cobalt-iron-nickel-boron (CoFeNiB). In addition, the second free magnetic pattern 155 may include a magnetic alloy layer realized by doping at least one of the above listed alloys (i.e., FeNi, FeNiB, CoFeNi, and CoFeNiB) with a non-magnetic material (i.e., W, Mo, Ta, Ti, Zr, or Hf).

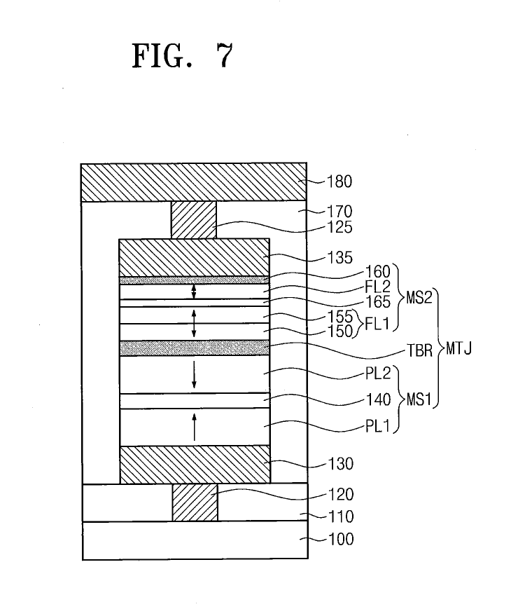

FIG. 7 is a cross-sectional view illustrating a magnetic memory device according to some embodiments of the inventive concepts. In the present embodiment, the same elements as described in the embodiment of FIG. 4 will be indicated by the same reference numerals or the same reference designators. For ease and convenience in explanation, the descriptions of the same elements as in the embodiment of FIG. 4 will be omitted or mentioned briefly. In other words, differences between the present embodiment and the embodiment of FIG. 4 will be mainly described hereinafter.

Referring to FIG. 7, a second magnetic structure MS2 may include a first free layer FL1, a second free layer FL2 on the first free layer FL1, a non-magnetic metal layer 165 between the first free layer FL1 and the second free layer FL2, and a capping layer 160 on the second free layer FL2.

The non-magnetic metal layer 165 may include a non-magnetic metal material. For example, the non-magnetic metal material may include at least one of Hf, Zr, Ti, Ta, W, Mo, Cr, or any alloy thereof. The second free layer FL2 may be coupled to the first free layer FL1 by the non-magnetic metal layer 165 such that the second free layer FL2 may have a perpendicular magnetization direction parallel to the magnetization direction of the first free layer FL1. The non-magnetic metal layer 165 may have a thickness of about 10 Å or less. In certain embodiments, the non-magnetic metal layer 165 may be omitted.

In some embodiments, the second free layer FL2 may include at least one of Fe, Co, Ni, or any alloy thereof. In addition, the second free layer FL2 may further include a non-magnetic metal material. The non-magnetic metal material of the second free layer FL2 may include at least one of Ta, Ti, Zr, Hf, B, W, Mo, or Cr. For example, the second free layer FL2 may include Fe or Co and may include the non-magnetic metal material (e.g., boron). The second free layer FL2 may not contain nickel (Ni) or may contain a little nickel, and, thus, the nickel content of the second free magnetic pattern 155 of the first free layer FL1 may be greater than that of the second free layer FL2.

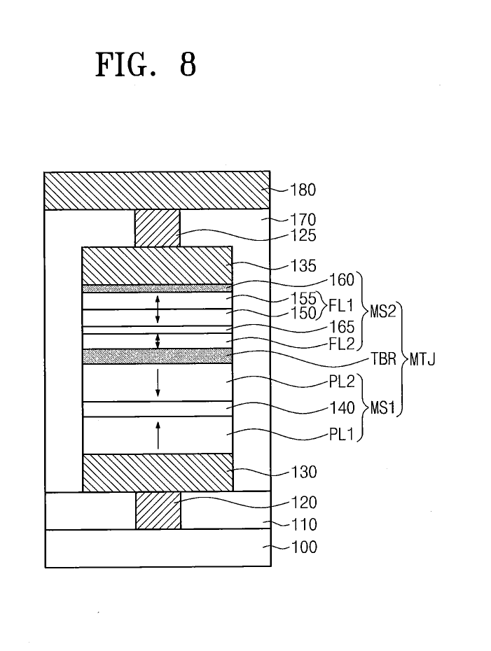

FIG. 8 is a cross-sectional view illustrating a magnetic memory device according to some embodiments of the inventive concepts. In the present embodiment, the same elements as described in the embodiment of FIG. 7 will be indicated by the same reference numerals or the same reference designators. For ease and convenience in explanation, the descriptions of the same elements as in the embodiment of FIG. 7 will be omitted or mentioned briefly. In other words, differences between the present embodiment and the embodiment of FIG. 7 will be mainly described hereinafter.

Referring to FIG. 8, a second free layer FL2 may be provided on the tunnel barrier layer TBR. A second free layer FL1 may be spaced apart from the tunnel barrier layer TBR with the second free layer FL2 interposed therebetween. The non-magnetic metal layer 165 may be provided between the first free layer FL1 and the second free layer FL2. In other words, the first free layer FL1 according to some embodiments of the inventive concepts may be spaced apart from the tunnel barrier layer TBR, and at least one additional free layer (e.g., the second free layer FL2) may be disposed between the first free layer FL1 and the tunnel barrier layer TBR.

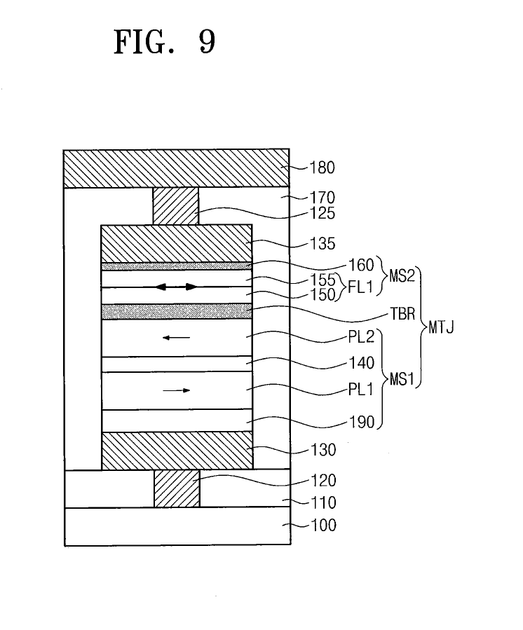

FIG. 9 is a cross-sectional view illustrating a magnetic memory device according to some embodiments of the inventive concepts. In the present embodiment, the same elements as described in the embodiment of FIG. 4 will be indicated by the same reference numerals or the same reference designators. For ease and convenience in explanation, the descriptions of the same elements as in the embodiment of FIG. 4 will be omitted or mentioned briefly. In other words, differences between the present embodiment and the embodiment of FIG. 4 will be mainly described hereinafter.

Referring to FIG. 9, the third type magnetic tunnel junction pattern MTJ3 of FIG. 3A may be provided on the substrate 100. Unlike the magnetic memory devices described above, a magnetic tunnel junction pattern MTJ according to the present embodiment may include magnetic layers having magnetization directions substantially parallel to the top surface of the substrate 100.

A first magnetic structure MS1 may include a pinning layer 190, a first pinned layer PL1, an exchanged coupling layer 140, and a second pinned layer PL2. The first pinned layer PL1 may be disposed between the pinning layer 190 and the exchange coupling layer 140, and the second pinned layer PL2 may be disposed between the exchange coupling layer 140 and a tunnel barrier layer TBR. In other words, the first magnetic structure MS1 according to the present embodiment may have a multi-layered structure that includes the pinned layers PL1 and PL2 having magnetization directions substantially parallel to the top surface of the substrate 100, e.g., horizontal magnetization directions.

The magnetization direction of the first pinned layer PL1 may be fixed by the pinning layer 190. The exchange coupling layer 140 may couple the second pinned layer PL2 to the first pinned layer PL1 in such a way that the magnetization direction of the second pinned layer PL2 is anti-parallel to the magnetization direction of the first pinned layer PL1.

The pinning layer 190 may include an anti-ferromagnetic material. For example, the pinning layer 190 may include at least one of platinum-manganese (PtMn), iridium-manganese (IrMn), manganese oxide (MnO), manganese sulfide (MnS), manganese-tellurium (MnTe), or manganese fluoride (MnF).

The first pinned layer PL1 may include a ferromagnetic material. For example, the first pinned layer PL1 may include at least one of cobalt-iron-boron (CoFeB), cobalt-iron (CoFe), nickel-iron (NiFe), cobalt-iron-platinum (CoFePt), cobalt-iron-palladium (CoFePd), cobalt-iron-chromium (CoFeCr), cobalt-iron-terbium (CoFeTb), or cobalt-iron-nickel (CoFeNi). The exchange coupling layer 140 may include at least one of ruthenium (Ru), iridium (Ir), or rhodium (Rh).

The second pinned layer PL2 may include a ferromagnetic material. For example, the second pinned layer PL2 may include at least one of cobalt-iron-boron (CoFeB), cobalt-iron (CoFe), nickel-iron (NiFe), cobalt-iron-platinum (CoFePt), cobalt-iron-palladium (CoFePd), cobalt-iron-chromium (CoFeCr), cobalt-iron-terbium (CoFeTb), or cobalt-iron-nickel (CoFeNi).

A second magnetic structure MS2 may include a first free layer FL1 and a capping layer 160, which are sequentially stacked on the tunnel barrier layer TBR. The second magnetic structure MS2 may include at least one free layer FL1 having a magnetization direction substantially parallel to the top surface of the substrate 100, e.g., a horizontal magnetization direction.

The first free layer FL1 may include a first free magnetic pattern 150 on the tunnel barrier layer TBR, and a second free magnetic pattern 155 on the first free magnetic pattern 150. In some embodiments, the first free magnetic pattern 150 may include cobalt-iron-boron (CoFeB), and the second free magnetic pattern 155 may include at least one of iron-nickel (FeNi), iron-nickel-boron (FeNiB), cobalt-iron-nickel (CoFeNi), or cobalt-iron-nickel-boron (CoFeNiB). In addition, the second free magnetic pattern 155 may be additionally doped with a non-magnetic material (i.e., W, Mo, Ta, Ti, Zr, or Hf).

Meanwhile, even though not shown in the drawings, the fourth type magnetic tunnel junction pattern MTJ4 of FIG. 3B may be provided on the substrate 100. In this case, similarly to the embodiment described above with reference to FIG. 6, the first magnetic structure MS1 of FIG. 9 may be disposed on the top surface of the tunnel barrier layer TBR and the second magnetic structure MS2 of FIG. 9 may be disposed under the tunnel barrier layer TBR.

The magnetic memory device according to some embodiments of the inventive concepts may include a free layer having a bi-layered structure. One layer of the free layer may be formed of an alloy including iron (Fe) and nickel (Ni), which are composed at a suitable content ratio. Thus, the switching current of the magnetic memory device may be reduced and the TMR characteristic of the magnetic memory device may be improved.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

1. A magnetic memory device comprising:
a magnetic tunnel junction pattern comprising a first free layer, a pinned layer, and a tunnel barrier layer between the first free layer and the pinned layer,
wherein the first free layer comprises:
a first free magnetic pattern having a first surface in direct contact with the tunnel barrier layer and a second surface opposite to the first surface; and
a second free magnetic pattern in contact with the second surface of the first free magnetic pattern,
wherein the second free magnetic pattern comprises iron-nickel (FeNi), and
wherein a nickel content of the second free magnetic pattern ranges from about 10 at % to about 30 at %.

2. The magnetic memory device of claim 1, wherein the second free magnetic pattern further comprises at least one of cobalt (Co) or boron (B).

3. The magnetic memory device of claim 1, wherein the nickel content of the second free magnetic pattern is greater than that of the first free magnetic pattern.

4. The magnetic memory device of claim 1, wherein the first free magnetic pattern comprises cobalt-iron-boron (CoFeB).

5. The magnetic memory device of claim 1, wherein a thickness of the second free magnetic pattern is smaller than a thickness of the first free magnetic pattern.

6. The magnetic memory device of claim 1, wherein a thickness of the first free layer ranges from about 10 Å to about 20 Å, and
wherein a thickness of the second free magnetic pattern ranges from about 3 Å to about 10 Å.

7. The magnetic memory device of claim 1, further comprising:
a non-magnetic metal layer adjacent to the first free layer; and
a second free layer spaced apart from the first free layer with the non-magnetic metal layer interposed therebetween,
wherein the nickel content of the second free magnetic pattern is greater than that of the second free layer.

8. The magnetic memory device of claim 1, further comprising:
a capping layer spaced apart from the tunnel barrier layer with the first free layer interposed therebetween,
wherein the capping layer comprises a metal oxide.

9. The magnetic memory device of claim 1, wherein the pinned layer comprises a plurality of pinned layers,
wherein the plurality of pinned layers comprises:
a first pinned layer adjacent to the tunnel barrier layer; and
a second pinned layer spaced apart from the tunnel barrier layer with the first pinned layer interposed therebetween,
the magnetic memory device further comprising:
an exchange coupling layer between the first and second pinned layers.

10. The magnetic memory device of claim 9, wherein the first pinned layer comprises:
a first magnetic layer adjacent to the tunnel barrier layer; and
a second magnetic layer spaced apart from the tunnel barrier layer with the first magnetic layer interposed therebetween, the second magnetic layer being in contact with the first magnetic layer.

11.-15. (canceled)

16. A magnetic memory device comprising:
a magnetic tunnel junction pattern comprising a free layer, a pinned layer, and a tunnel barrier layer between the free layer and the pinned layer,
wherein the free layer comprises:
a first free magnetic pattern adjacent to the tunnel barrier layer; and
a second free magnetic pattern spaced apart from the tunnel barrier layer with the first free magnetic pattern interposed therebetween, the second free magnetic pattern adjacent to the first free magnetic pattern,
wherein the first free magnetic pattern comprises cobalt-iron-boron (CoFeB),
wherein the second free magnetic pattern comprises iron-nickel (FeNi), and
wherein a nickel content of the second free magnetic pattern ranges from about 10 at % to about 30 at %.

17. The magnetic memory device of claim 16, wherein the second free magnetic pattern further comprises boron (B), and
wherein a boron content of the second free magnetic pattern ranges from about 1 at % to about 25 at %.

18. The magnetic memory device of claim 16, wherein the first and second free magnetic patterns are magnetically connected to each other.

19.-23. (canceled)

24. A magnetic memory device comprising:
a magnetic tunnel junction pattern comprising a free layer, a pinned layer, and a tunnel barrier layer between the free layer and the pinned layer;
wherein the free layer comprises:
a first free magnetic pattern; and
a second free magnetic pattern on the first free magnetic pattern such that the first free magnetic pattern is between the second free magnetic pattern and the tunnel barrier layer, the second free magnetic pattern having a nickel content that is greater than a nickel content of the first free magnetic pattern.

25. The magnetic memory device of claim 24, wherein the nickel content of the second free magnetic pattern has an atomic percent between about 10 at % and about 30 at % and the nickel content of the first free magnetic pattern has an atomic percent between about 0.01 at % and about 5 at %.

26. The magnetic memory device of claim 25, wherein a boron content of the first free magnetic pattern has an atomic percent between about 1 at % and about 25 at % and a boron content of the second free magnetic pattern has an atomic percent between about 1 at % and about 25 at %.

27. The magnetic memory device of claim 24, wherein the pinned layer comprises a first pinned layer, a second pinned layer, and an exchange coupling layer between the first pinned layer and the second pinned layer;
wherein the exchange coupling layer comprises one of ruthenium, iridium, and rhodium.

28. The magnetic memory device of claim 24, wherein a thickness of the first free magnetic pattern is greater than a thickness of the second free magnetic pattern;
wherein a thickness of the first free layer is between about 10 Å and about 20 Å; and
wherein a thickness of the second free magnetic pattern is between about 3 Å and about 10 Å.

29. The magnetic memory device of claim 24, wherein the tunnel barrier layer has first and second surfaces that form interfaces with the free layer and the pinned layer, respectively; and
wherein a magnetization direction of the free layer and a magnetization direction of the pinned layer are substantially perpendicular to the first and second surfaces of the tunnel barrier layer.

30. The magnetic memory device of claim 24, wherein the tunnel barrier layer has first and second surfaces that form interfaces with the free layer and the pinned layer, respectively; and
wherein a magnetization direction of the free layer and a magnetization direction of the pinned layer are substantially parallel to the first and second surfaces of the tunnel barrier layer.
